(19) United States
(12) Patent Application Publication
(10) Pub. No.: US 2026/0012187 A1
(43) Pub. Date: Jan. 8, 2026

(54) HYBRID DELAY-LOCKED LOOP

(71) Applicants: SHIBAURA INSTITUTE OF TECHNOLOGY, Tokyo (JP); MURATA MANUFACTURING CO., LTD., Nagaokakyo-shi (JP)

(72) Inventors: Retdian NICODIMUS, Saitama (JP); Hajime KANDO, Nagaokakyo-shi (JP); Yasuhide TAKASE, Nagaokakyo-shi (JP)

(73) Assignees: SHIBAURA INSTITUTE OF TECHNOLOGY, Tokyo (JP); MURATA MANUFACTURING CO., LTD., Nagaokakyo-shi (JP)

(21) Appl. No.: 19/325,560

(22) Filed: Sep. 11, 2025

Related U.S. Application Data
(63) Continuation of application No. PCT/JP2024/009351, filed on Mar. 11, 2024.

(30) Foreign Application Priority Data
Mar. 16, 2023 (JP) 2023-041704

(51) Int. Cl. H03L 7/081; H03L 7/095; H03L 7/099

(52) U.S. Cl. CPC H03L 7/0818; H03L 7/095; H03L 7/0992

(57) ABSTRACT

A hybrid delay-locked loop Includes: a digital control loop including a digital phase detector having a dead zone; and an analog control loop including an analog phase detector that operates in the dead zone.

### CROSS-REFERENCE TO RELATED APPLICATIONS

This is a continuation application of PCT International Patent Application No. PCT/JP2024/009351 filed on Mar. 11, 2024, designating the United States of America, which is based on and claims priority of Japanese Patent Application No. 2023-041704 filed on Mar. 16, 2023. The entire disclosures of the above-identified applications, including the specifications, drawings and claims are Incorporated herein by reference in their entirety.

### FIELD

The present disclosure relates to a hybrid delay-locked loop including a digital control loop and an analog control loop.

### BACKGROUND

Recently, software-defined radios have been attracting attention and N-pass filters and mixer-first receivers have been proposed. Such circuits need multiphase clocks. There are two types of multiphase clock generation: one using a register, as in NPL 1; and the other using a delay-locked loop (DLL), as in NPL 2.

### CITATION LIST

### Non Patent Literature

NPL 1: “Advantages of Shift Registers Over DLLs for Flexible Low Jitter Multiphase Clock Generation”, X. Gao, B. Nauta, E. Klumperink, Circuits and Systems II: Express Briefs, IEEE Trans., vol. 55, no. 3, pp. 244-248, March 2008.
NPL 2: “Clock buffer chip with multiple target automatic skew compensation”, R. B. Watson, Jr., R. B. Iknaian, IEEE J. Solid-State Circuits, vol. 30, pp. 1267-1276, November 1995.

### SUMMARY

### Technical Problems

Although register-based multiphase clock generation circuits are said to have better jitter characteristics than DLL-based ones, the reference clock frequency of N×f_{CK} (N: odd number) or N×f_{CK}/2 (N: even number) is required to create an N-phase clock with the frequency of f_{CK}.

When a wide frequency-variable range is required steady-state frequency fluctuations due to increased loop gain are a problem in DLLs that use analog control. In DLLs that use digital control (all-digital DLLs), since the variable range can be expanded without changing the loop gain, steady-state frequency fluctuations can be reduced, but higher resolution (more control bits) is required and the time until the output converges also gets longer.

The present disclosure is conceived in view of the above-described circumstances and provides a delay-locked loop capable of high-speed and stable operation.

### Solutions to Problems

In other words, the present disclosure relates to a hybrid delay-locked loop Including: a digital control loop that includes a digital phase detector having a dead zone; and an analog control loop that includes an analog phase detector that operates in the dead zone.

### Advantageous Effects

The hybrid delay-locked loop according to the present disclosure enables high-speed and stable operation with a relatively simple structure.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram of a delay-locked loop.

FIG. 2 is a block diagram of a phase detector.

FIG. 3 is a timing chart diagram for illustrating control loop operation.

FIG. 4 is a block diagram of an all-digital delay-locked loop.

FIG. 5 is a graph showing the relationship between the number of control bits and normalized frequency deviation.

FIG. 6 is a block diagram of a hybrid DLL.

FIG. 7 is a diagram illustrating a dead zone and a range in which an analog control loop operates.

FIG. 8A is a block diagram of Simulink.

FIG. 8B is a diagram illustrating the output result of MATLAB (registered trademark) simulation.

FIG. 9A is a block diagram of a digital phase detector.

FIG. 9B is a block diagram of an analog phase detector.

FIG. 10 is a model diagram of a triggered counter.

FIG. 11 is a model diagram of a charge pump and a loop filter.

FIG. 12 is a model diagram of a delay line with a frequency counter and a frequency limit.

FIG. 13 is a model diagram of a four-stage delay line.

FIG. 14 is a MATLAB simulation model diagram.

FIG. 15 is a graph showing the output waveforms of a counter and phase detectors.

FIG. 16 is a graph showing a transition of the output frequency of the hybrid DLL.

FIG. 17 is a graph showing the output waveforms of a reference clock and the hybrid DLL.

FIG. 18 is a graph showing the output waveform of each phase of the hybrid DLL.

### DESCRIPTION OF EMBODIMENT

The present disclosure relates to a hybrid delay-locked loop including: a digital control loop including a digital phase detector having a dead zone; and an analog control loop including an analog phase detector that operates in the dead zone. Specifically, the hybrid delay-locked loop according to the present disclosure is a hybrid control-type DLL configured by combining an analog control loop and a digital control loop, where a dead zone for a phase difference to be detected is provided for the phase detector for digital control loop, the phase detector for digital control loop is operated in this dead zone, and the phase detector for analog control loop is stopped outside the dead zone. The dead zone Indicates the range of phase difference in which the phase detector cannot detect the input phase difference and cannot perform phase detection operation. The dead zone phase difference is desirably at least twice the control range of phase difference of the analog phase detector.

In such a hybrid delay-locked loop, control loop switching between analog and digital can be achieved with a relatively simple structure. Specifically, the frequency can be shifted to a target frequency at high speed and stabilized at the target frequency by reducing the number of control bits for the digital control phase detector, providing a wider dead zone, and switching to the analog control loop when the digital control phase detector enters the dead zone.

In the delay-locked loop, the analog control loop may further include a charge pump, a loop filter, and a lock detector, and the digital control loop may further include at least one of a shift register or a counter. With this, the hybrid delay-locked loop can be configured with a simple structure.

In the delay-locked loop, in the digital control loop, a control frequency may be roughly adjusted by rough adjustment of a delay time. In the analog control loop, the control frequency roughly adjusted in the digital control loop may be finely adjusted by fine adjustment of a delay time. Thus, in the delay-locked loop, the digital control loop may be configured to roughly adjust a delay time of a delay line. The analog control loop may then be configured to finely adjust the delay time to precisely match the period of an input reference clock. These loop control the delay time of the delay line, which, in turn, controls the output frequency of the DLL. In other words, by roughly controlling the frequency by digital control and finely controlling the roughly controlled frequency by analog control, the number of control bits can be more reduced and the circuit of the digital control can be more simplified than the case of digital control alone, and the range of the frequency to be controlled can be more widened than the case of analog control alone. This can reduce the number of control bits for the digital control loop, thereby reducing the scale, size, and power consumption of the circuit.

In the digital control loop, there is a dead zone where the digital phase detector cannot respond even if there is a phase difference, resulting in frequency fluctuations caused by the dead zone. To reduce such frequency fluctuations, increasing the number of control bits is necessary, and this results in an increase in the scale, size, and power consumption of the circuit. By reducing the number of control bits for the digital control phase detector, providing a wider dead zone, and switching to the analog control loop when the digital control phase detector enters the dead zone, the frequency can be shifted to a target frequency at high speed and stabilized at the target frequency.

### Embodiment

The following will describe various control schemes in DLLs. Specifically, a control scheme that uses an analog discrete-time control loop as well as a control scheme that uses a digital control loop for all-digital DLL will be described. A hybrid control scheme that combines the analog control loop and the digital control loop can reduce steady-state errors and speed up transient responses.

### 1. Introduction

Recently, software-defined radios have been attracting attention and N-pass filters and mixer-first receivers have been proposed. Such circuits need multiphase clocks. There are two types of multiphase clock generation: one using a register; and the other using a delay-locked loop (DLL). Although register-based multiphase clock generation circuits are said to have better jitter characteristics than DLL-based ones, the reference clock frequency of N×f_{CK} (N: odd number) or N×f_{CK}/2 (N: even number) is required to create an N-phase clock with the frequency of f_{CK}. Since the output frequency is the same as the input frequency in the DLL, requirements for reference clocks are relaxed.

When a wide frequency-variable range is required, steady-state frequency fluctuations due to increased loop gain are a problem in DLLs that use analog control. In DLLs that use digital control (all-digital DLLs), since the variable range can be expanded without changing the loop gain, steady-state frequency fluctuations can be reduced, but higher resolution (more control bits) is required and the time until the output converges also gets longer. In order to overcome these problems, hybrid DLLs combining analog and digital control loops are suitable. In such a hybrid DLL, switching between the analog control loop and the digital control loop can be achieved with a relatively simple structure.

The following describes principles and problems of DLL. An outline of a hybrid DLL then follows and simulation results are shown.

### 2. DLL

Principles and problems of DLL will be described here.

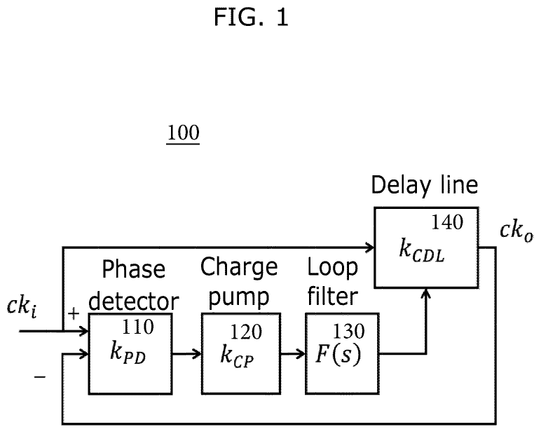

First, a DLL that uses an analog control loop will be described. FIG. 1 is a block diagram of DLL 100 that uses an analog control loop. This DLL 100 includes phase detector 110, charge pump 120, loop filter 130, and delay line 140. If a DLL transfer function is defined by T(s)=Cₖ₀/Cₖᵢ, transfer function T(s) is expressed by the following equation.

$$\begin{matrix}[ Math . 1 ] & \\ T ( s ) = \frac{{c}_{ko}}{{c}_{ki}} = \frac{{k}_{PD} {k}_{CP} {k}_{CDL} F ( s )}{1 + {k}_{PD} {k}_{CP} {k}_{CDL} F ( s )} & ( Equation 1 )\end{matrix}$$

Here, k_{PD} denotes the gain of phase detector 110, k_{CP} denotes the gain of charge pump 120, F(s) represents the transfer function of loop filter 130, k_{CDL} denotes the gain of delay line 140, and s denotes a Laplace's variable.

Here, assuming that charge pump 120 and loop filter 130 are included in a lossless integrator, Equation 2 is obtained.

$$\begin{matrix}[ Math . 2 ] & \\ {k}_{CP} F ( s ) = \frac{{k}_{CP}}{s τ} = \frac{{k}_{CP} {I}_{CP}}{sC} & ( Equation 2 )\end{matrix}$$

Here, when T=C/I_{CP} is defined, I_{CP} denotes the charge and discharge current of charge pump 120 and C denotes the capacitance of loop filter 130. When Equation 2 is substituted into Equation 1, the following equation is obtained.

$$\begin{matrix}[ Math . 3 ] & \\ T ( s ) = \frac{{c}_{ko}}{{c}_{ki}} = \frac{{k}_{PD} {k}_{CP} {k}_{CDL} {I}_{CP}}{sC + {k}_{PD} {k}_{CP} {k}_{CDL} {I}_{CP}} & ( Equation 3 )\end{matrix}$$

Here, when charge pump 120 and loop filter 130 are represented by a linear transfer function expressed by, for example, Equation 4, the DLL transfer function can be obtained by Equation 5.

$$\begin{matrix}[ Math . 4 ] & \\ {k}_{CP} F ( s ) = \frac{{k}_{CP}}{1 + s τ} = \frac{{k}_{CP} {I}_{CP}}{{I}_{CP} + sC} & ( Equation 4 )\end{matrix}$$

$$\begin{matrix}[ Math . 5 ] & \\ T ( s ) = \frac{{k}_{PD} {k}_{CP} {k}_{CDL} {I}_{CP}}{sC + ( 1 + {k}_{PD} {k}_{CP} {k}_{CDL} ) {I}_{CP}} & ( Equation 5 )\end{matrix}$$

Here, Equation 3 and Equation 5 show that the order of the DLL transfer function is determined only by the order of the loop filter. In other words, if loop filter 130 is a first-order filter, DLL 100 will not be unstable.

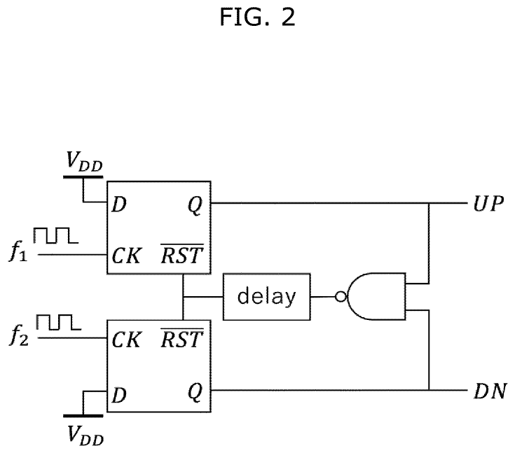

A phase detector used in many DLLs includes the D flip-flop illustrated in FIG. 2. The assumption is that the two inputs f₁ and f₂ of the phase detector are square waves. When the rising edges of f₁ and f₂ are detected by this D flip-flop, the UP signal and the DN signal go high (logic 1), respectively. In the circuit illustrated in FIG. 2, when f₁ rises first, the UP signal goes high and the output of the loop filter rises due to the charging current of the charge pump. Next, when f₂ rises, the DN signal goes high and the discharge current of the charge pump cancels out the charging current. With this, when both UP and DN go high, which causes the output of the loop filter to be constant, the D flip-flop is reset via the NAND gate and the output goes low (logic 0). When the time difference (phase difference) between the rises of f1 and f2 becomes small, the D flip-flop is reset before it rises completely and normal operation is not possible in the actual circuit. As a result, there is an input range (dead zone) where the phase detector cannot respond when the phase difference between f1 and f2 is near 0 degrees. To solve the dead zone problem, delay is added to a reset signal.

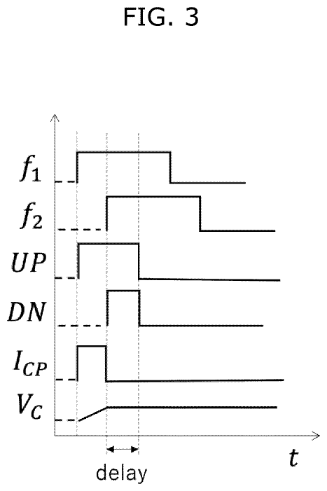

FIG. 3 illustrates an outline of time waveforms of these operations. FIG. 3 is a timing chart diagram for illustrating control loop operation. Vc in the figure is the output signal of the loop filter and is the control signal of the delay line. Looking at the operation of the phase detector, the control signal of the delay cell changes only near the rising edge of the input. In other words, the control signal is a discrete control signal, not continuous time. The control loop is temporarily non-functional until the output of the phase detector is reset and the input is next rising. At this time, when the loop gain is large, the transient response of the control signal may not converge although the transfer function is theoretically stable. Since the realization of a wider frequency-variable range requires a higher loop gain in situations where the amplitude of the control signal is limited, this makes steady-state frequency fluctuations problematic for conventional DLLs.

Next, all-digital DLL 200 will be described.

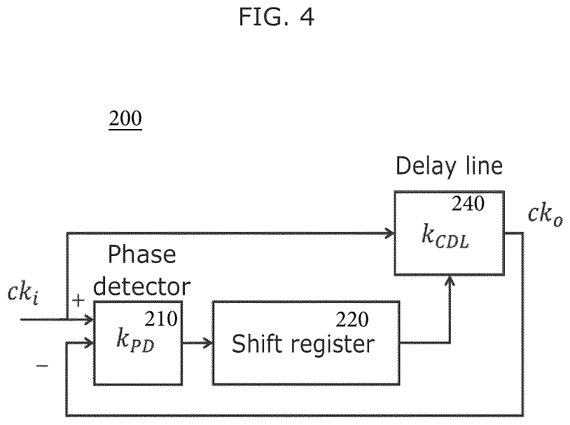

In an all-digital DLL, a shift register is used instead of an analog control loop that includes a charge pump and a loop filter. FIG. 4 is a block diagram of all-digital DLL 200 that includes phase detector 210, shift register 220, and delay line 240. Shift register 220 used in all-digital DLL 200 is referred to as a bidirectional shift register and shifts a control bit to right or left in accordance with the signal of phase detector 210. Since the delay time of delay line 240 is discretely controlled, higher resolution (higher bits) of the digital control signal is used to inhibit steady-state frequency fluctuations. When the control signal is a thermometer code, shift register 220 gets longer with an Increase in the number of control steps and clock propagation delay becomes problematic in a high frequency range. When a large increase in control steps is required, a counter may be used Instead of a shift register and perform control using binary weighted codes.

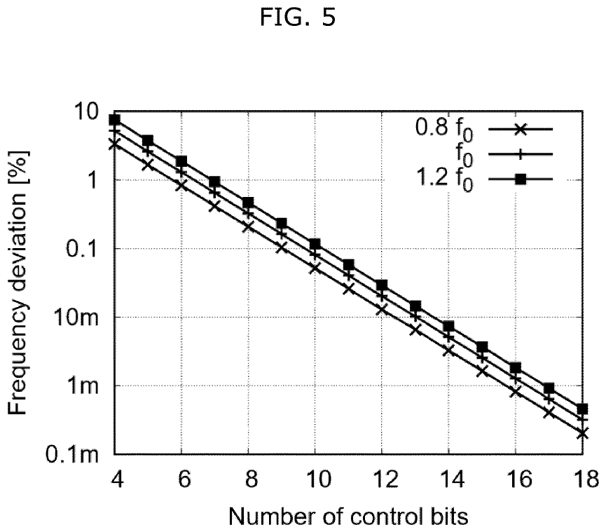

FIG. 5 illustrates the number of control bits and minimum values of steady-state frequency deviation in an all-digital DLL. FIG. 5 is a graph showing the relationship between the number of control bits and normalized frequency deviation. The center frequency of the reference clock is f₀, the variable width is defined in the range of minus 20% and plus 20%, and the frequency deviation is normalized at the frequency of the reference clock (0.8f₀, 1.0f₀, 1.2f₀). For example, when f₀=100 MHz and the frequency deviation is within 10 kHz, the most severe condition is when the clock frequency is 120 MHz (1.2f₀), and the normalized frequency deviation is 10 kHz/120 MHz=8.34%. From FIG. 5, the required number of control bits is 15 bits, which is not easily achievable. Furthermore, higher bits are required to maintain the same frequency deviation as the frequency variation increases.

### 3. Hybrid DLL

Next, hybrid DLL 300 will be described.

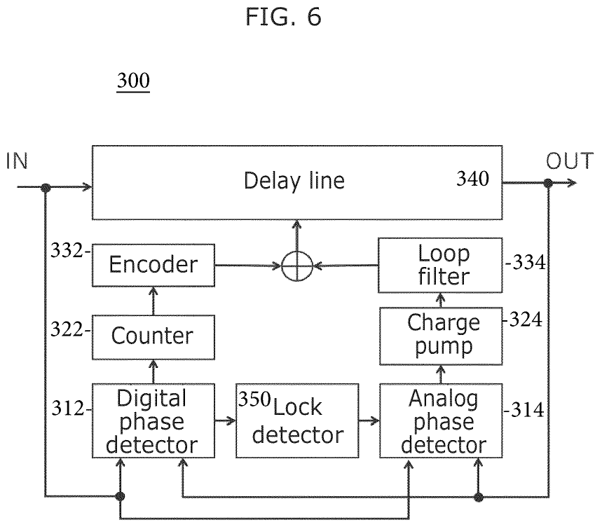

To achieve a DLL with a wide frequency-variable range and low steady-state frequency error, a combination of an analog control loop that uses a charge pump and a digital control loop that uses a shift register or a counter is possible. Here, the DLL using both analog and digital control loops is called a hybrid DLL. An outline of the proposed hybrid DLL 300 is shown in FIG. 6. FIG. 6 is a block diagram of hybrid DLL 300 and Includes digital phase detector 312, analog phase detector 314, lock detector 350, counter 322, charge pump 324, encoder 332, loop filter 334, and delay line 340.

This hybrid DLL 300 uses two phase detectors with different operations. Analog phase detector 314 uses the phase detector illustrated in FIG. 2. Digital phase detector 312 can only go high on either UP or DN at any given time. Digital phase detector 312 does not have a reset function, and the high or low state is determined at the rising edge of the input and held until the next rising edge. For example, suppose that UP goes high when the rising edge of IN comes first. If the next rising edge of IN also comes first, the UP signal remains high. However, if OUT comes first on the next rising edge, the UP signal goes low and the DN signal goes high.

A dead zone is provided for digital phase detector 312, and the outputs UP and DN of digital phase detector 312 go low when the phase difference of the input enters the dead zone. The state where UP and DN go low simultaneously is detected by lock detector 350, and analog phase detector 314 is activated. When UP or DN of digital phase detector 312 goes high again, the output of charge pump 324 is reset and analog phase detector 314 is stopped. As a result, at any given time, only one of the digital control loop and the analog control loop is operational. The digital control loop is used for rough or coarse adjustment, and its low resolution is sufficient. The digital control loop has a large step width, resulting in high loop gain and fast transient response. The analog control loop, in contrast, is used for fine adjustment and covers only a narrow frequency range, allowing the charge pump gain to be low and reducing steady-state frequency fluctuations.

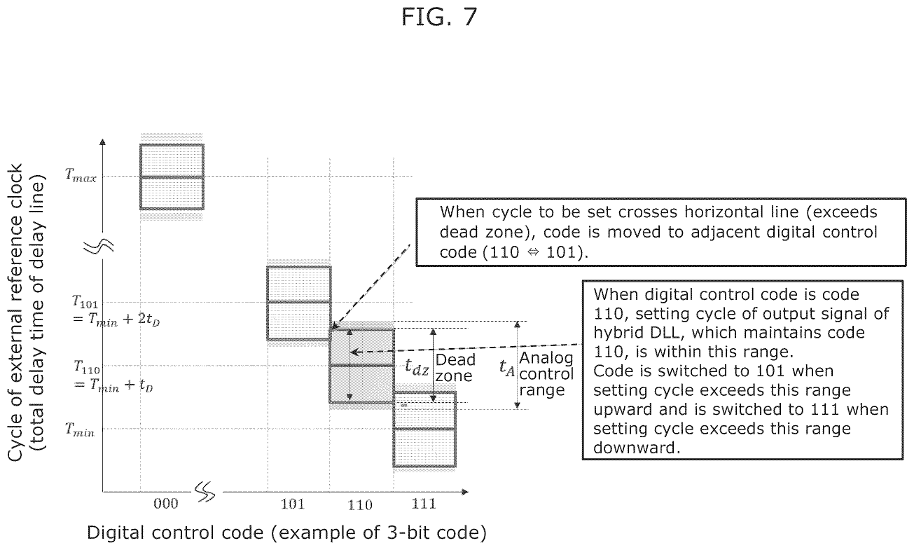

FIG. 7 is a diagram Illustrating the dead zone and the range in which the analog control loop operates (analog control range t_{A}). Here, the maximum frequency of the signal output by the hybrid DLL is fₘₐₓ, the minimum frequency of the signal output by the hybrid DLL is fₘᵢₙ, the minimum cycle of the signal output by the hybrid DLL is Tₘᵢₙ=1/fₘₐₓ, the maximum cycle of the signal output by the hybrid DLL is Tₘₐₓ=1/fₘᵢₙ, the control bit of the digital phase detector is n, the time step width of the digital control loop is t_{D}=(Tₘₐₓ−Tₘᵢₙ)/(2ⁿ−1), and the center value of the cycle in a particular digital control code is T_{CODE}, the dead zone width is set to t_{dz}, the dead zone is set to be in a range greater than (T_{CODE}−t_{dz}/2) and less than (T_{CODE}+t_{dz}/2), and the analog control range is set to be in a range greater than (T_{CODE}−t_{A}/2) and smaller than (T_{CODE}+t_{A}/2). Thus, the dead zone is set to include the analog control range.

When the dead zones of adjacent digital control codes (adjacent codes) do not overlap, an area of a delay time not included in any dead zone is generated. When the delay time of delay line 340 to synchronize with the external reference clock is within that region, the analog control loop does not operate and only the digital control loop does. This causes the digital control code to oscillate without being determined to be one of the two adjacent codes. To prevent the digital control code from wavering, the dead zone width may be set to be greater than the time step width of the digital control loop, i.e., t_{dz}>t_{D}. In other words, the dead zones of adjacent codes may be set to overlap.

If the dead zone overlaps a code next to an adjacent code, the adjacent code becomes Invalid, and therefore, t_{dz}<2t_{D} is set.

The analog control range may be set to be greater than the dead zone width, i.e., t_{A}>t_{dz} to allow the digital control loop to get out of the dead zone. In the hybrid DLL, the upper limit of the width of the analog control range is theoretically allowed to be (Tₘₐₓ−Tₘᵢₙ)>t_{A}. Since the loop gain when (Tₘₐₓ−Tₘᵢₙ)>t_{A} is set in the hybrid DLL is smaller than the loop gain when (Tₘₐₓ−Tₘᵢₙ)=t_{A} in an all-analog-controlled analog DLL, the stability of the cycle of the signal output by the hybrid DLL is Improved (i.e., cycle fluctuations and frequency fluctuations are reduced).

In the actual design, t_{A} is designed and optimized by the loop gain according to the fluctuation width of the output signal cycle targeted by the hybrid DLL.

### 4. MATLAB Model

Since MATLAB's Simulink is used for functional verification, a functional block model is needed to configure the DLL. This section describes the details of each functional block.

### 4.1 Frequency Switching Reference Clock

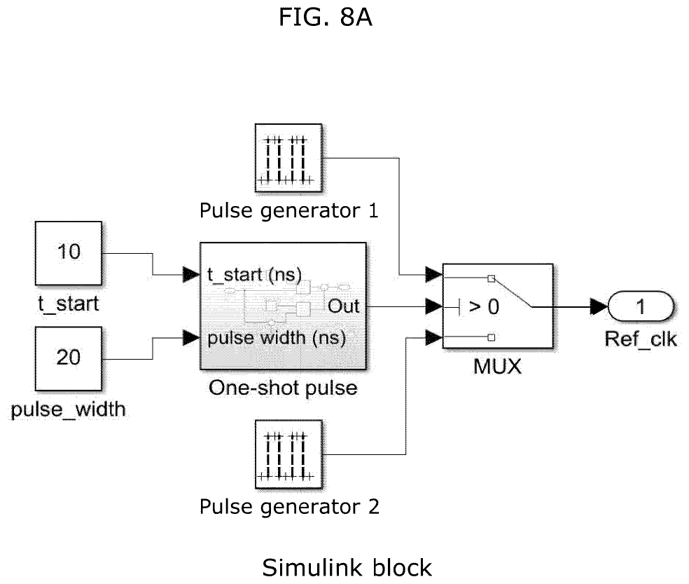

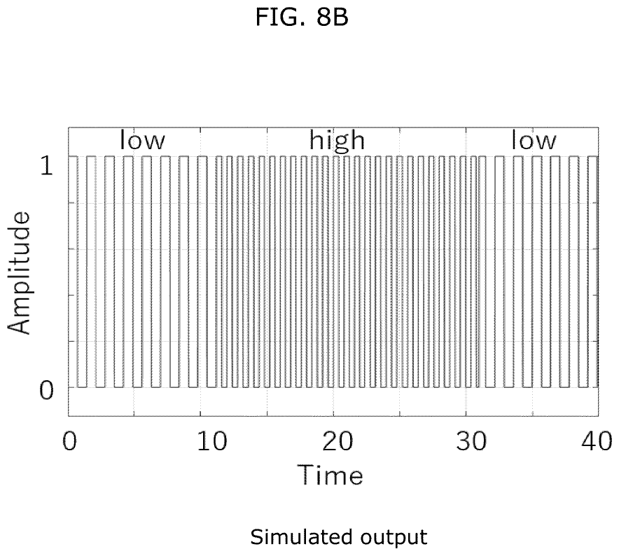

A reference clock with switchable frequency is needed to verify the operation of the DLL. FIG. 8A is a block diagram of Simulink, and FIG. 8B shows output results of a MATLAB simulation. As shown in FIG. 8A, Simulink uses two pulse generation blocks and a switch to switch the frequency. Here, a single pulse is used for the switching timing, as shown in FIG. 8B. All values are normalized. In the example in FIG. 8B, the frequency of the square wave Increases (high) at time t=10 s and remains so for 20 seconds. The set value is a value normalized to an arbitrary cycle.

### 4.2 Phase Detector

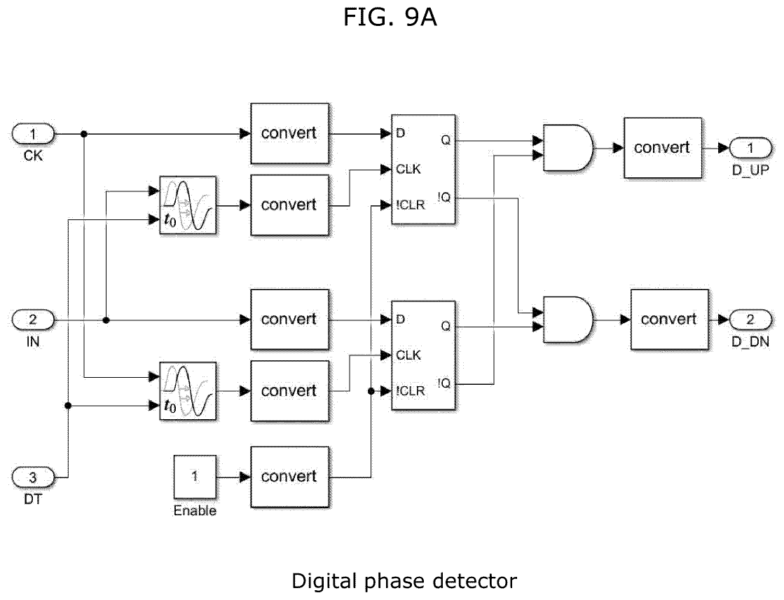

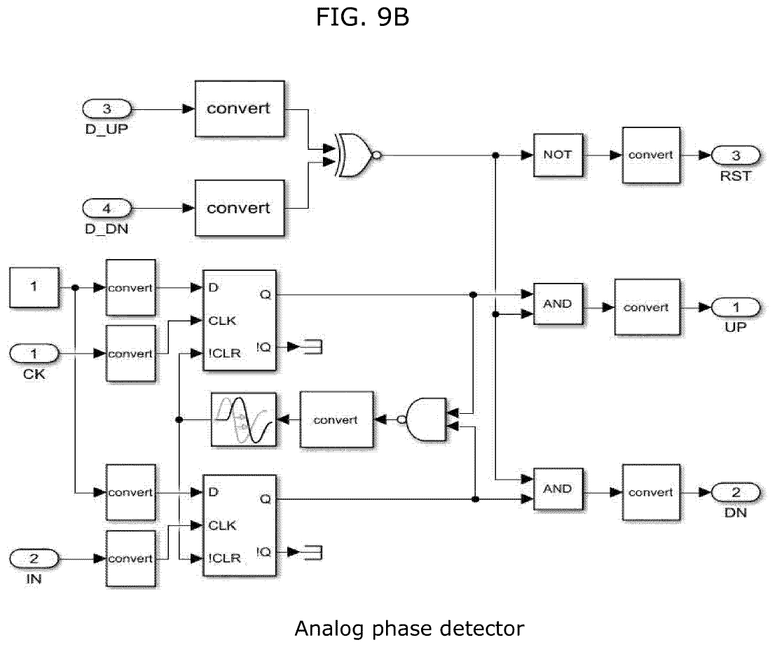

Phase detection models are shown in FIG. 9A and FIG. 9B. FIG. 9A is a block diagram of a digital phase detector. FIG. 9B is a block diagram of an analog phase detector. As illustrated in FIG. 9A, the digital phase detector includes D flip-flops and AND gates, and adds transmission delay to the input to create a dead zone. In the present embodiment, the dead zone of the digital phase detector is 2.4 times the control range of the phase difference of the analog phase detector to ensure stable operation of the digital phase detector, but the digital phase detector can operate even when the dead zone is twice the control range. As illustrated in FIG. 9B, the trigger of the analog phase detector is made by an exclusive-OR (XOR) gate and the output of the digital phase detector. The Inverted version of that signal is used as a reset signal for the charge pump (RST). Since a logic block such as a D flip-flop handles Boolean data, data type conversion is used between the logic block and another block that handles numerical data. For data type conversion, a convert block is used.

### 4.3 Triggered Counter

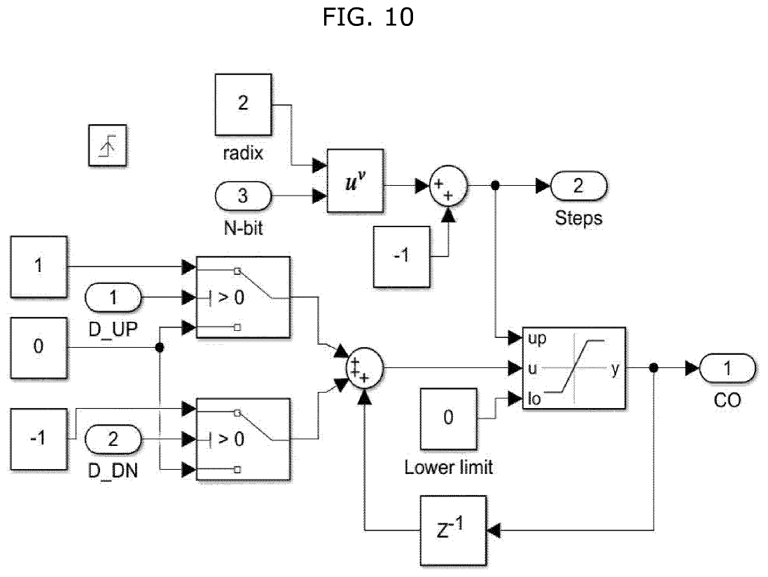

FIG. 10 is a model diagram of a triggered counter. The counter Integrates +1 or −1 depending on the output of the digital phase detector, i.e., increments or decrements the value output. The integration is achieved by a lossless Integrator with finite outputs. A saturation block is used to limit the output. The minimum value is set to 0 according to the specification of the propagation delay block used in the delay line, and the maximum value is equal to the number of control steps and is represented by the following equation.

$$\begin{matrix}[ Math . 6 ] & \\ Steps = {2}^{n} - 1 & ( Equation 6 )\end{matrix}$$

However, n is the number of bits of the digital control signal. The counter operates on the rising edge of the clock. The outputs of this block are the counter output CO and the number of steps (Steps).

### 4.4 Charge Pump and Loop Filter

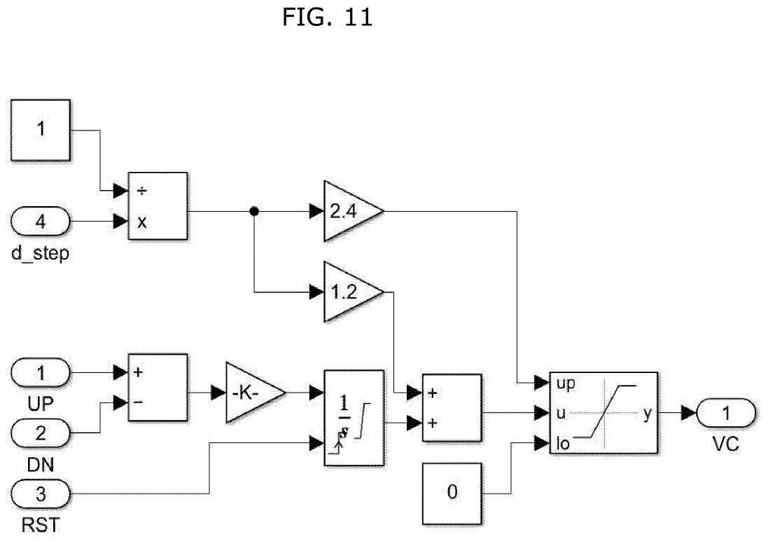

FIG. 11 is a model diagram of a charge pump and a loop filter. The charge pump takes a difference that is the analog phase detector output signal and Integrates the difference using the loop filter represented by the lossless integration block 1/s. dₛₜₑₚ is a value output from the delay line block and is represented by Equation 7 below.

$$\begin{matrix}[ Math . 7 ] & \\ {d}_{step} = \frac{\frac{1}{{f}_{min}} - \frac{1}{{f}_{max}}}{N \times Steps} & ( Equation 7 )\end{matrix}$$

However, N is the number of phases. dₛₜₑₚ is the delay amount of a delay cell corresponding to 1LSB of the digital control signal. The delay cell constitutes a delay line. The delay control amount of the analog control loop is set to 2.4×dₛₜₑₚ, and the center value of the loop filter output is 1.2×dₛₜₑₚ. Theoretically, these coefficients should be greater than or equal to 1, but the dead zone value needs to be considered to ensure reliable operation of the digital phase detector.

### 4.5 Delay Line

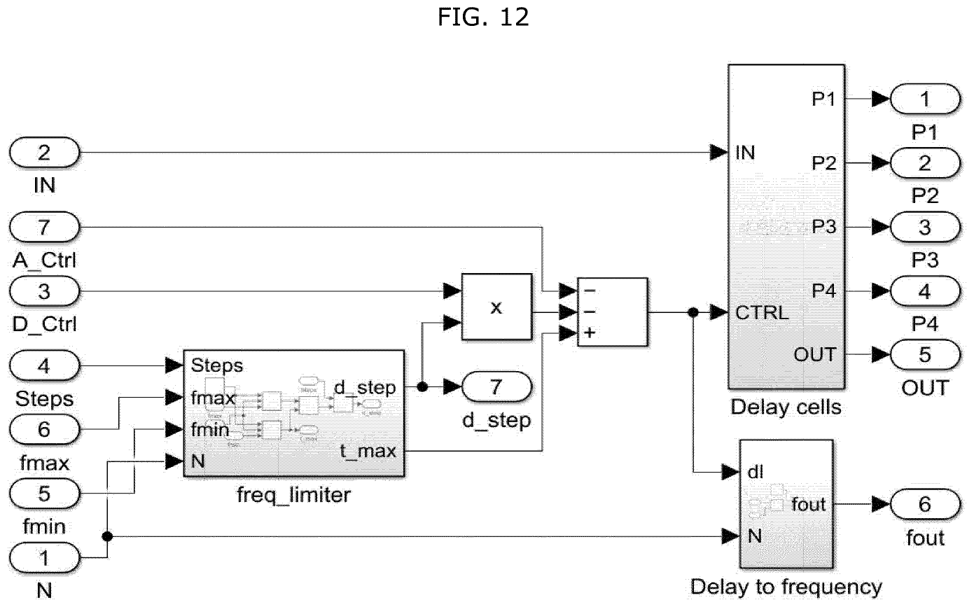

FIG. 12 is a model diagram of a delay line with a frequency counter and a frequency limit. The delay cell control signal CTRL is equal to the delay time t_{d} of the delay cell and is represented by Equation 8.

$$\begin{matrix}[ Math . 8 ] & \\ CTRL = {t}_{d} = {t}_{max} - {D}_{ctrl} \times {d}_{step} - {A}_{ctrl} & ( Equation 8 )\end{matrix}$$

$${t}_{max} = \frac{1}{N \times {f}_{min}}$$

Frequency fₒᵤₜ of the DLL output is represented by Equation 9 from the delay time t_{d} in Equation 8.

$$\begin{matrix}[ Math . 9 ] & \\ {f}_{out} = \frac{1}{N \times {t}_{d}} & ( Equation 9 )\end{matrix}$$

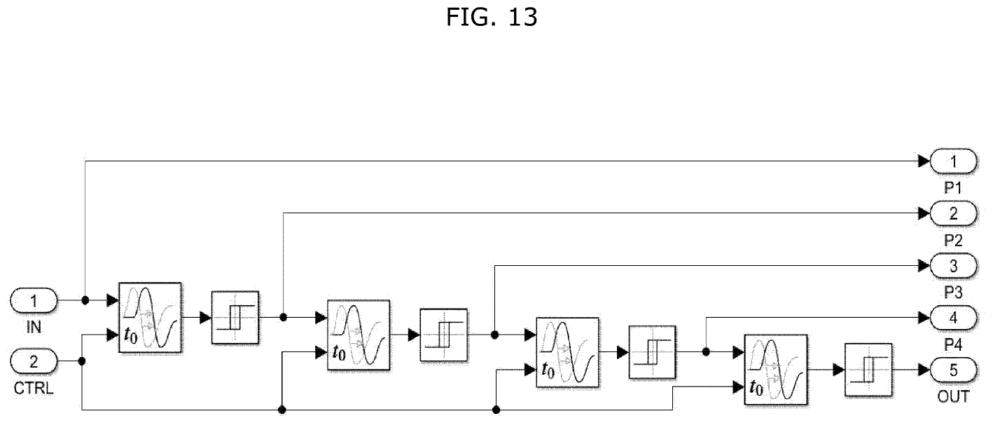

FIG. 13 is a model diagram of a 4-stage delay line. As Illustrated in FIG. 13, the delay line includes four-stage delay cells and assumes a four-phase clock (N=4). A delay cell uses a variable propagation delay block and a relay block. The delay cell may operate without a relay block, but abnormal values may be output until the output of the delay cell is determined.

### 5. Simulation Results

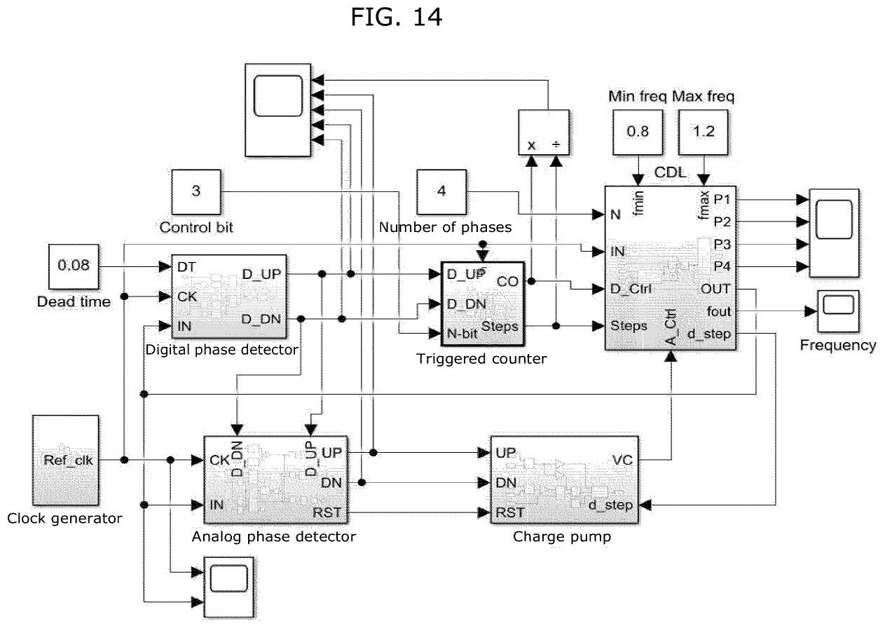

Simulation is performed using MATLAB's Simulink. FIG. 14 is a MATLAB simulation model diagram. Table 1 shows simulation parameters. In the MATLAB simulation, the behavior of the hybrid DLL is checked using the simulation parameters shown in Table 1. fₘᵢₙ, fₘₐₓ, and dead zone (dead time) are normalized values. When changing control bit n (Control bit n), the value of the dead zone also needs to be changed accordingly. The reference clock may be set to switch from 1.1 Hz to 0.95 Hz.

TABLE 1

| Parameter | Value | |
|---|---|---|
| Control bit n | 3 | bits |
| Number of phase N | 4 | |
| fₘᵢₙ | 0.8 | Hz |
| fₘₐₓ | 1.2 | Hz |
| dead time | 0.08 | s |

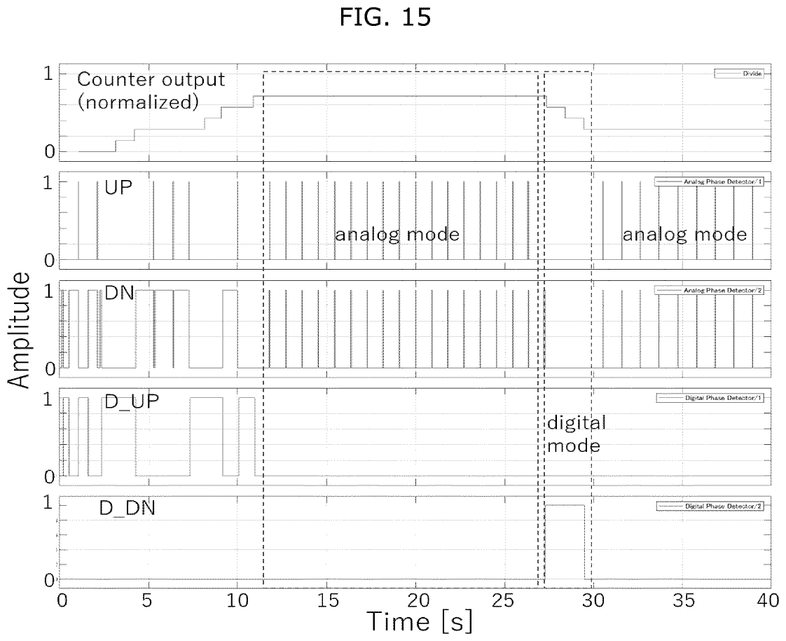

FIG. 15 is a graph showing the output waveforms of the counter and the phase detectors. As can be seen from FIG. 15, when the digital phase detector operates, either D_UP or D_DN goes high and the counter output changes. At this time, the analog phase detector stops and the UP signal and the DN signal remain low. However, when the digital phase detector stops, the analog phase detector operates and the UP signal and the DN signal are output. This result shows that the control loop switches normally between the analog mode and the digital mode.

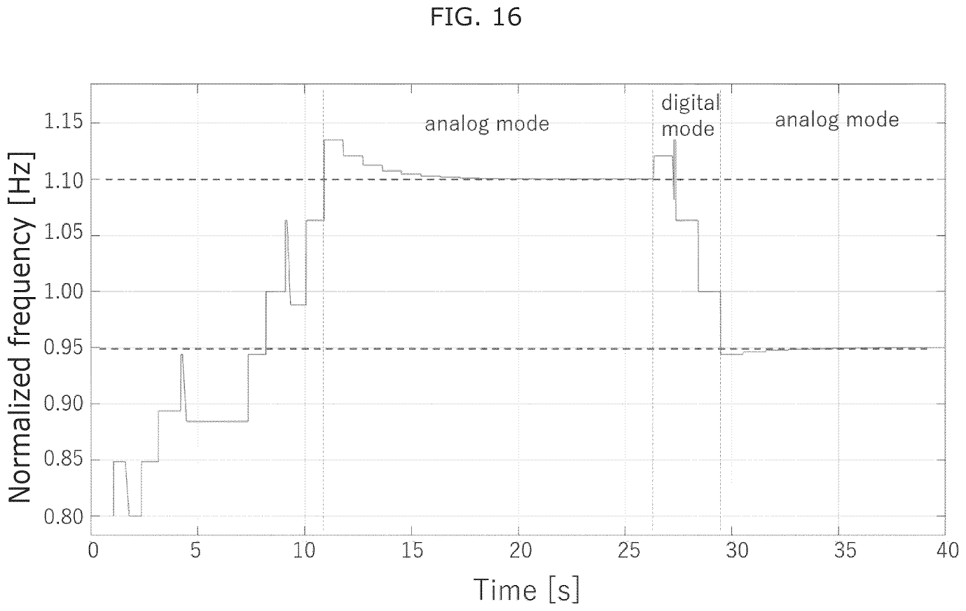

FIG. 16 is a graph showing a transition of the hybrid DLL output frequency. The output is invalid around time t=0 s because the output after the second stage of the delay line is not defined in the initial setting. At time t=4 s, a 1.1-Hz reference clock comes in and the DLL enters a transient state. A large frequency Increase can be observed since the digital phase detector operates first. The digital phase detector enters the dead zone, switches to the analog control loop, and the output frequency gradually converges to 1.1 Hz. When the frequency of the reference clock is changed to 0.95 Hz at time t=25 s, the digital phase detector leaves the dead zone and the digital control loop operates again. When the output frequency decreases rapidly and reaches around 0.95 Hz, the output frequency converges again slowly to 0.95 Hz in the analog control loop. This result shows that a fast transient response and a stable steady-state response are obtained.

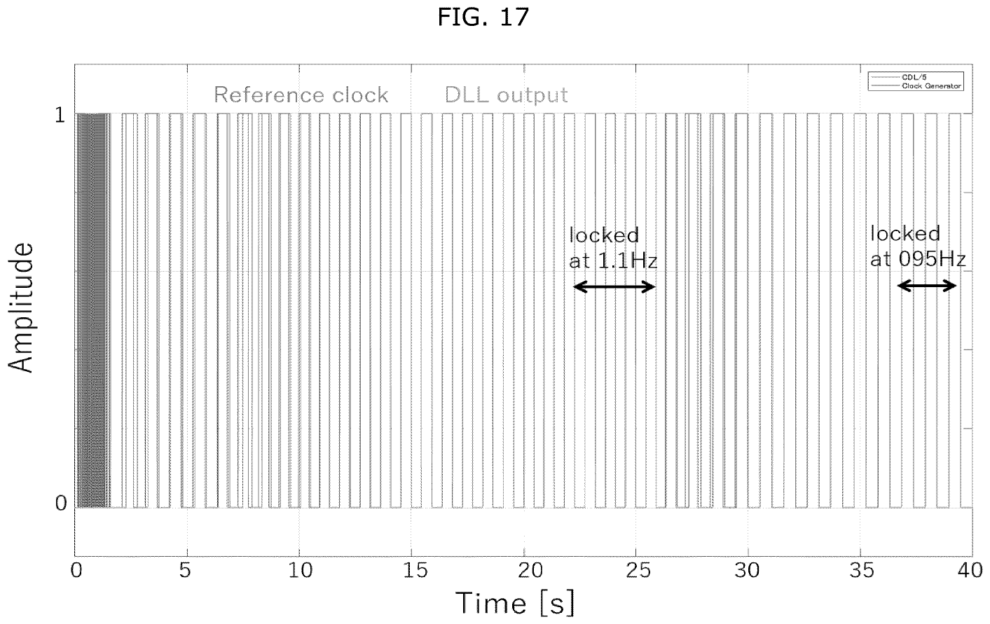

FIG. 17 is a graph showing the waveforms of the reference clock and the hybrid DLL output. As Illustrated in FIG. 17, the DLL output is synchronized with the reference clock when locked.

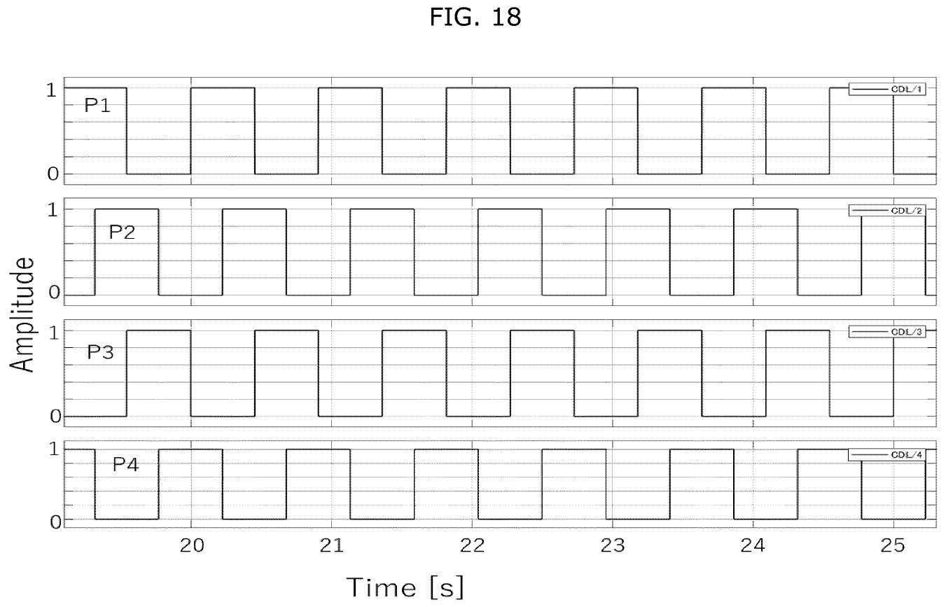

FIG. 18 is a graph showing the output waveform of each phase of the hybrid DLL. The figure shows the 4-phase output (P1-P4) waveforms of the DLL. From the figure, it can be observed that each phase of the DLL output is shifted by 90 degrees in the synchronized state. The above results show that the hybrid DLL is operating normally under the conditions provided as a design example.

### 6. Conclusion

We clarified the problems of DLLs in multiphase clocks that require a wide frequency-variable range, and proposed a hybrid DLL that combines analog control and digital control. We created a model of this DLL using MATLAB Simulink and verified its operation. As a result of the verification, switching of the control loop and convergence of the output were observed, confirming that this DLL works properly. The fast transient response of the DLL and its stable operation in steady state were also verified.

### OTHER EMBODIMENTS

Although a hybrid delay-locked loop according to the present disclosure has been described based on an embodiment, the hybrid delay-locked loop according to the present disclosure is not limited to the embodiment described above. Other embodiments achieved by combining any of the elements in the embodiment or variations obtained by various modifications to the embodiment which may be conceived by those skilled in the art, as well as various devices Incorporating the above-described hybrid delay-locked loop are also included in the present disclosure so long as they do not depart from the essence of the present disclosure.

### INDUSTRIAL APPLICABILITY

The hybrid delay-locked loop according to the present disclosure can be used for, for Instance, various wireless systems including software-defined radios.

1. A hybrid delay-locked loop (DLL) comprising:
a digital control loop including a digital phase detector having a dead zone; and
an analog control loop including an analog phase detector that operates in the dead zone.

2. The hybrid DLL according to claim 1, wherein
the dead zone has a time span that is less than an analog control range, greater than a time step width of the digital control loop, and less than twice the time step width of the digital control loop.

3. The hybrid DLL according to claim 1, wherein
the analog control loop further includes a charge pump, a loop filter, and a lock detector, and
the digital control loop further includes at least one of a shift register or a counter.

4. The hybrid DLL according to claim 1, wherein
in the digital control loop, a control frequency is roughly adjusted by rough adjustment of a delay time, and
in the analog control loop, the control frequency roughly adjusted in the digital control loop is finely adjusted by fine adjustment of a delay time.

5. A hybrid delay-locked loop (DLL), comprising:
a delay line configured to receive an input clock signal and, in response, generate an output clock signal having a controllable delay time relative to the input clock signal;
a digital control loop coupled to the delay line, the digital control loop including a digital phase detector and being configured to generate a digital control signal to provide a coarse adjustment to the controllable delay time, wherein the digital phase detector is configured to cease generating corrective signals when a phase difference between the input clock signal and the output clock signal is within a dead zone; and
an analog control loop coupled to the delay line, the analog control loop including an analog phase detector and being configured to generate an analog control signal to provide a fine adjustment to the controllable delay time, wherein the analog control loop is configured to be active when the phase difference is within the dead zone.

6. The hybrid DLL according to claim 5,
wherein the digital control loop is configured to provide the coarse adjustment with a discrete time step width, and the dead zone has a time span greater than the discrete time step width.

7. The hybrid DLL according to claim 6,
wherein the dead zone has a time span that is less than twice the discrete time step width.

8. The hybrid DLL according to claim 6,
wherein the analog control loop is configured to provide the fine adjustment within an analog control range, and the time span of the dead zone is less than a time span of the analog control range.

9. The hybrid DLL according to claim 5, wherein:
the analog control loop further includes a charge pump and a loop filter; and
the digital control loop further includes a counter configured to generate a count, and an encoder configured to generate the digital control signal based on the count.

10. The hybrid DLL according to claim 5, further comprising:
a lock detector configured to detect when the phase difference has entered the dead zone by detecting when the digital phase detector ceases to generate the corrective signals.

11. The hybrid DLL according to claim 10,
wherein the lock detector is configured to activate the analog control loop in response to detecting that the phase difference has entered the dead zone.

12. The hybrid DLL according to claim 5,
wherein the analog phase detector Includes a phase-frequency detector Including a pair of D flip-flops and a reset logic gate.

13. The hybrid DLL according to claim 5,
wherein the delay line comprises a plurality of controllable delay cells connected in series.

14. The hybrid DLL according to claim 12,
wherein the delay line is configured to generate a plurality of phase-shifted output clock signals from taps between the plurality of controllable delay cells.

15. A method for controlling a delay time in a delay line, the method comprising:
generating, via a digital control loop including a digital phase detector, a digital control signal based on a phase difference between an input clock signal and an output clock signal from the delay line;
applying the digital control signal to the delay line to provide a coarse adjustment to a delay time of the output clock signal;
ceasing the generation of the digital control signal when the phase difference enters a dead zone;
In response to the phase difference entering the dead zone, activating an analog control loop including an analog phase detector;
generating, via the activated analog control loop, an analog control signal based on the phase difference; and
applying the analog control signal to the delay line to provide a fine adjustment to the delay time.

16. The method according to claim 15,
wherein generating the digital control signal includes incrementing or decrementing a counter based on the phase difference.

17. The method according to claim 15,
wherein activating the analog control loop is performed by a lock detector.

18. The method according to claim 15,
wherein generating the analog control signal includes driving a charge pump based on the phase difference and filtering an output of the charge pump with a loop filter.

19. The method according to claim 15,
wherein the coarse adjustment includes changing the delay time in discrete time steps, and the fine adjustment includes changing the delay time in a continuous manner within a range smaller than one of the discrete time steps.

20. The method according to claim 15,
further comprising deactivating the analog control loop when the phase difference moves outside of the dead zone.
